(19) United States
(12) Patent Application Publication
(10) Pub. No.: US 2013/0168143 A1
(43) Pub. Date: Jul. 4, 2013

(54) CIRCUIT BOARD

(71) Applicants: Seung Wook Park, Seoul (KR); Mi Jin Park, Gyunggi-do (KR); Christian Romero, Gyunggi-do (KR); Young Do Kweon, Seoul (KR)

(72) Inventors: Seung Wook Park, Seoul (KR); Mi Jin Park, Gyunggi-do (KR); Christian Romero, Gyunggi-do (KR); Young Do Kweon, Seoul (KR)

(73) Assignee: SAMSUNG ELECTRO-MECHANICS CO., LTD., Gyunggi-do (KR)

(21) Appl. No.: 13/454,680

(22) Filed: Apr. 24, 2012

(30) Foreign Application Priority Data
Dec. 29, 2011 (KR) 1020110146293

(51) Int. Cl. H05K 1/09; H05K 1/02

(52) U.S. Cl. 174/257; 174/250

(57) ABSTRACT

Disclosed herein is a circuit board including: an insulating material; a build-up layer formed on one surface of the insulating material, and including at least one circuit layer and at least one insulating layer; and a metal layer formed on the other surface of the insulating material and electrically disconnected from the circuit layer.

### CROSS REFERENCE TO RELATED APPLICATION

This application claims the benefit of Korean Patent Application No. 10-2011-0146293, filed on Dec. 29, 2011, entitled “Circuit Board”, which is hereby incorporated by reference in its entirety into this application.

### BACKGROUND OF THE INVENTION

1. Technical Field

The present invention relates to a circuit board.

2. Description of the Related Art

In general, a circuit board has been widely used over an electronics industry, such as home appliances, portable electronic devices, or the like. When technically classifying the circuit board, a double sided circuit board has been mainly used, the double sided circuit board having one surface and the other surface on which patterns are formed, and a hole formed so as to connect one surface and the other surface to each other, the hole having a surface processed with a conductive material.

However, a mobile device has been recently demanded to be slim. In order to meet such a demand, by using a single sided circuit board, it is manufactured that a height of an assembly is minimized, such that a height of a battery thereof is increased or it may be mounted in a portion of the mobile device.

Therefore, there is an increased demand for a slim type board capable of being formed in a single surface rather than a double sided circuit board.

In the single sided circuit board, a circuit is formed on only any one of one surface or the other surface of an insulating material, a hole for connecting the one surface to the other surface is not included, a lower portion thereof serves as only a base, whereby manufacturing costs may be reduced.

However, in the single sided circuit board, the circuit layer is formed only in one direction, such that warpage may easily occur at the time of forming the board. In addition, it is not easy to control parasitic capacitance, such that performance of the product may be degraded.

### SUMMARY OF THE INVENTION

The present invention has been made in an effort to provide a circuit board having improved performance by preventing occurrence of warpage and reducing an entire parasitic capacitance.

According to a preferred embodiment of the present invention, there is provided a circuit board including: an insulating material; a build-up layer formed on one surface of the insulating material, and including at least one circuit layer and at least one insulating layer; and a metal layer formed on the other surface of the insulating material and electrically disconnected from the circuit layer.

The circuit board may further include a first solder resist layer formed on the build-up layer.

Here, the first solder resist layer may include an opening part exposing a portion of an outermost circuit layer included in the build-up layer.

In addition, the circuit board may further include a surface treatment layer formed on the outermost circuit layer exposed through the opening part.

In addition, the circuit board may further include a second solder resist layer formed on the metal layer.

Here, the circuit layer may be made of copper (Cu).

In addition, the metal layer may be selected from the group consisting of copper (Cu), nickel (Ni), silver (Ag), or an alloy thereof.

In addition, the metal layer may be formed of a plurality of layers.

Here, each of the metal layers may be made of different kinds of metals.

### BRIEF DESCRIPTION OF THE DRAWINGS

FIG. 1 is a cross-sectional view showing a structure of a circuit board according to a preferred embodiment of the present invention;

FIG. 2 is a graph showing a comparison of a frequency characteristics between the circuit board according to the preferred embodiment of the present invention and the circuit board of the prior art; and

FIGS. 3 to 6 shows a comparison of occurrence of warpage between the circuit board according to the preferred embodiment of the present invention and the circuit board of the prior art.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from preferred embodiments and the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

Hereinafter, preferred embodiments of the present invention will be described in detail with reference to the accompanying drawings.

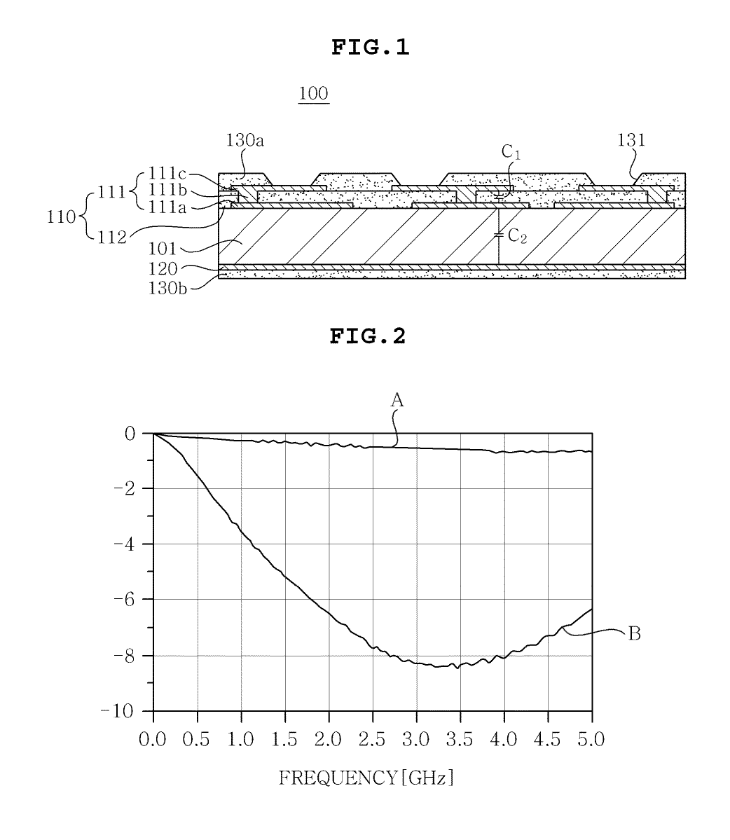

FIG. 1 is a cross-sectional view showing a structure of a circuit board according to a preferred embodiment of the present invention.

Referring to FIG. 1, the circuit board 100 according to the preferred embodiment of the present invention includes an insulating material 101, a build-up layer 110 formed on one surface of the insulating material 101, and a metal layer 120 formed on the other surface of the insulating material 101.

The circuit board 100 according to the preferred embodiment of the present invention may be applied to an interposer substrate, a printed circuit board, a semiconductor substrate, a multilayered low temperature co-fired ceramic (LTCC) substrate, a multilayered high temperature co-fired ceramic (HTCC) substrate, or the like, but it is not specifically limited thereto.

A resin insulating material may be used as the insulating material 101. A thermo-setting resin such as an epoxy resin, a thermo-plastic resin such as a polyimide resin, a resin having a reinforcement material such as a glass fiber or an inorganic filler impregnated therein, for example, a prepreg may be used as the resin insulating material. In addition, as the resin insulating material, a thermo-setting resin, and/or a photo-setting resin, or the like, may be used, but it is not specifically limited thereto.

As shown in FIG. 1, the build-up layer 110 according to the preferred embodiment of the present invention is formed on only one surface of the insulating material 101. The build-up layer 110 may include at least one circuit layer 111 and at least one insulating layer 112.

In FIG. 1, although the build-up layer 110 is shown to include one insulating layer 112 and two circuit layers 111a and 111c, this is only one embodiment and it may include a plurality of insulating layers and a plurality of circuit layers.

Here, likewise the insulating material 101 as described above, the resin insulating layer may be used as the insulating layer 112, but it is not specifically limited thereto.

In addition, any conductive metal for a circuit used in a circuit board field may be applied to the circuit layer 111 without limitation. Copper (Cu) is generally used in a circuit board.

The circuit layer 111 according to the preferred embodiment of the present invention may include a first circuit pattern 111a formed on the insulating material 101, a first via 111b connected to the first circuit pattern 111a, and a second circuit pattern 111c connected to the first via 111b, as shown FIG. 1.

In this case, parasitic capacitance C₁ may be generated between the first circuit pattern 111a and the second circuit pattern 111c.

The parasitic capacitance is formed due to a voltage difference between two conductors. In the present embodiment, due to the presence of the voltage difference between the first circuit pattern 111a and the second circuit pattern 111c that are the conductors, the parasitic capacitance may be generated between the two patterns.

The parasitic capacitance may be disregarded in the case in which a frequency is low, but impedance becomes low, as the frequency becomes high, to thereby increase a loss of a signal, such that performance of a product may be degraded.

In addition, as a distance between conductive layers is gradually close, in accordance with recent high integration of a semiconductor device, a value of the parasitic capacitance becomes increased.

As described above, as the value of the parasitic capacitance becomes increased, electrical characteristics of peripheral circuits, devices, or the like are deteriorated.

That is, in single sided circuit board in which the build-up layer is formed only in one direction as shown in the present embodiment, the parasitic capacitance is determined by the number of layers to be stacked. Since an interval between the build-up layers is very small, the value of the parasitic capacitance formed between the layers is increased and the parasitic capacitance in each interlayer of the build-up layers is the same as the case in which the build-up layers are connected to each other in series, such that it is not easy to reduce the value of the entire parasitic capacitance of the board.

Therefore, in the present embodiment, the metal layer 120 is formed on the insulating material 101 in an opposite direction of the build-up layer 110 at the time of forming the single sided circuit board, as shown in FIG. 1, whereby minimum parasitic capacitance is generated between the first circuit pattern 111a and the metal layer 120, thereby reducing the value of the entire parasitic capacitance of the single sided circuit board 100.

This may be more efficiently accomplished by implementing a thickness of the insulating material 101 to be significantly thicker than a thickness of the build-up layer 110. For example, the thickness of the insulating material 101 may be two times or more to the thickness of the build-up layer 110, but it is not specifically limited thereto.

That is, a distance between the first circuit pattern 111a and the metal layer 120 becomes significantly large, such that a very small value C₂ of the parasitic capacitance is generated. In addition, the parasitic capacitance C₂ is connected to the parasitic capacitance C₁ of the build-up layer 110 in series, such that a value connected in series between the very small value C₂ and the value C₁ which is not very small becomes small, and consequently, the value of the entire parasitic capacitance of the board is reduced.

As described above, in the single sided circuit board according to the preferred embodiment of the present invention, the metal layer is formed on the surface of the insulating material opposite to the surface thereof on which the build-up layer is formed, whereby it may be implemented such that the value of the entire parasitic capacitance of the board is small.

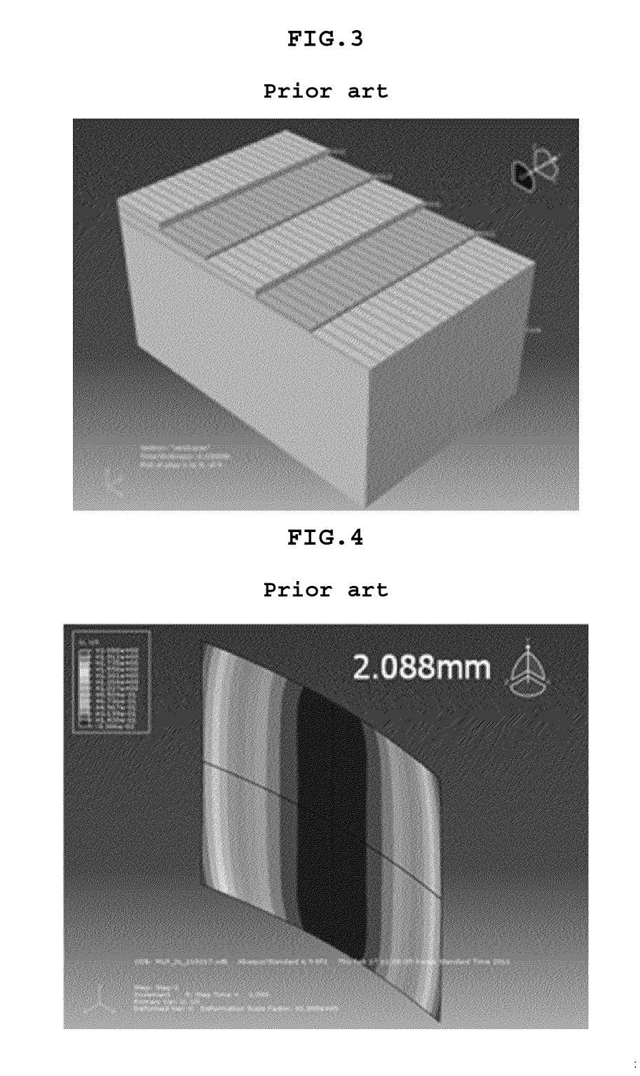

In addition, as the single sided circuit board is implemented such that the value of the entire parasitic capacitance of the board is small, it may be appreciated that the frequency characteristics of the single sided circuit board 110 according to the present embodiment are significantly improved as compared to the single sided circuit board in the prior art, as shown in FIG. 2.

Here, A represents frequency characteristics of the single sided circuit board according to the present embodiment and B represents frequency characteristics of the single sided circuit board of the prior art.

Referring to FIG. 2, it may be appreciated that a loss of the frequency of the single sided circuit board according to the present embodiment is significantly reduced compared to a loss of the frequency of the single sided circuit board of the prior art in a high frequency domain at GHz level.

In addition, the single sided circuit board 100 according to the present embodiment includes a metal layer 120 formed thereon, thereby preventing occurrence of warpage.

Here, the metal layer 120 may be selected from the group consisting of copper (Cu), nickel (Ni), silver (Ag), gold (Au), or an alloy thereof, but is not specifically limited thereto.

In addition, in FIG. 1, the metal layer 120 is formed of one layer. However, in the present embodiment, the metal layer 120 may be formed of a plurality of layers. In the case in which the metal layer 120 is formed of the plurality of layers, each layer may be made of different kinds of metals, but is not specifically limited thereto.

In general, in the case of a board formed only in one direction, warpage may occur due to an asymmetrical structure of the board itself. In this case, according to the present embodiment, the metal layer 120 is formed in an opposite direction based on the insulating material 101, which is a core, such that the asymmetrical structure is reinforced to be symmetrical to some extent, thereby making it possible to significantly reduce the occurrence of warpage of the board.

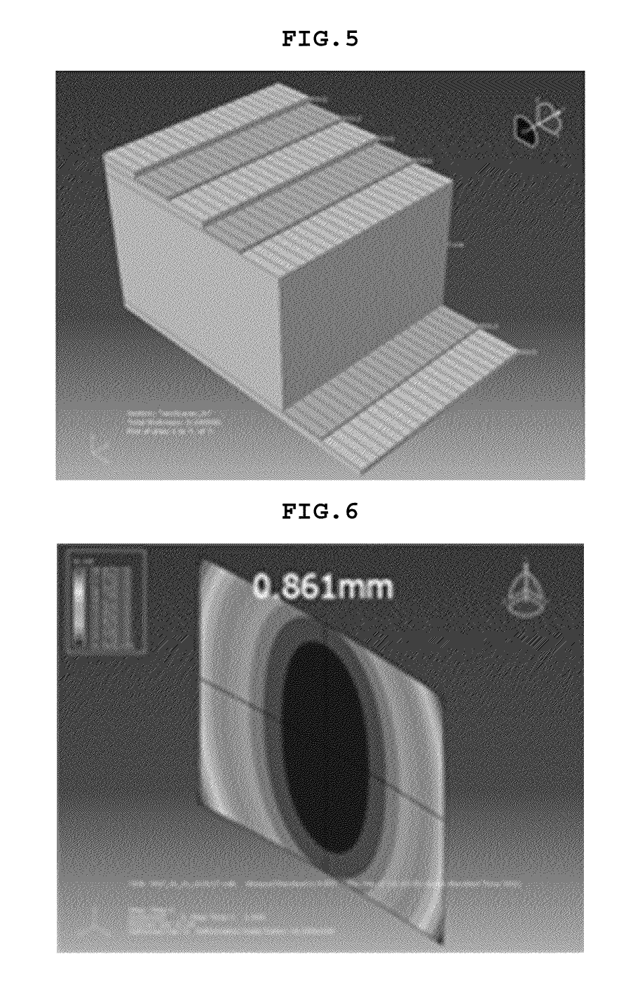

That is, as shown in FIGS. 3 to 6, it can be appreciated that the warpage degree of single sided circuit board according to the present embodiment is significantly reduced compared to that of the single sided circuit board of the prior art.

Here, FIG. 3 shows the single sided circuit board of the prior art, FIG. 4 shows the warpage degree of the single sided circuit board of the prior art, FIG. 5 shows the single sided circuit board according to the present embodiment and FIG. 6 shows the warpage degree of the single sided circuit board according to the present embodiment.

Meanwhile, the single sided circuit board 100 according to the present embodiment may be easily formed by using a double sided copper clad lamination (CCL) having a copper clad layer formed on the both sides of the insulating material.

That is, since the double sided copper clad lamination (CCL) basically has the copper clad layer formed on both sides thereof based on the insulating material, the formed copper clad layer may be used without additionally forming metal layers on the insulating material, such that the CCL may be easily manufactured without increase in manufacturing time and manufacturing costs.

In addition, in the present embodiment, the metal layer 120 may be formed by using the CCL as described above, but it is obvious that it may also be formed by performing a physical vapor deposition (PVD) method such as a sputtering method, a chemical vapor deposition (CVD) method such as an electroless plating method, or the like, on the insulating material 101.

In addition, in the present embodiment, the metal layer 120 may serve to reinforce ground characteristics for shielding electromagnetic compatibility (EMC) and improving frequency characteristics, but it is not specifically limited thereto.

In addition, as shown in FIG. 1, the single sided circuit board 100 according to the present embodiment may further include a first solder resist layer 130a formed on the build-up layer 110 and a second solder resist layer 130b formed on the metal layer 120.

In this case, the first solder resist layer 130a may include an opening part 131 exposing an outermost circuit layer of the build-up layer 110, for example, a portion of the second circuit pattern 111c, but it is not specifically limited thereto.

Here, the first solder resist layer 130a and the second solder resist layer 130b serve to protect the outermost circuit layer and the metal layer 120, respectively, and are formed for an electrical insulation.

The first solder resist layer 130a and the second solder resist layer 130b may be made of, for example, a solder resist ink, a solder resist film, an encapsulant, or the like, as known in the art, but it is not specifically limited thereto.

Here, in the case in which the solder resist is made of a film, it may be formed by a vacuum lamination method. In the case in which the solder resist is made of an ink, it may be generally formed by a screening printing method, a roller coating method, a curtain coating method, a spray coating method, or the like. In the case in which the solder resist is made of a semiconductor material using an insulating material, it may be formed by a coating method, or the like, used in manufacturing a LCD, a semiconductor, or the like.

Here, since each method of forming the solder resist has been already known in the art, a description thereof will be omitted.

In addition, as an example of the outermost circuit layer exposed through the opening part 131 of the first solder resist layer 130a, a surface treatment layer (not shown) may be formed on an exposed portion of the second circuit pattern 111c.

Any surface treatment layer which is known in the art may be used without limitation, but, it may be formed by for example, an electrolytic nickel and gold plating method, an electroless nickel immersion gold (ENIG) method, an electroless nickel autocatalytic gold (ENAG) method, an electroless nickel electroless palladium immersion gold (ENEPIG) method, an electroless nickel immersion palladium immersion gold (ENPIG) method, an immersion tin plating method, an organic solderability preservative (OSP) method, or the like.

As set forth above, with the single sided circuit board according to the preferred embodiment of the present invention, the metal layer electrically disconnected from the circuit layer is formed on the surface thereof opposite to the surface on which the circuit layer is formed, thereby reducing the entire parasitic capacitance of the board due to the parasitic capacitance between the circuit layer and the metal layer.

Further, according to the preferred embodiment of the present invention, a structure in which the entire parasitic capacitance of the board may be reduced is implemented, thereby improving performance of the single sided circuit board.

Further, with the single sided circuit board according to the preferred embodiment of the present invention, the metal layer is formed on the surface thereof opposite to the surface on which the circuit layer is formed, thereby reducing the warpage phenomenon, which may occur due to the build-up layer formed only in one direction.

Although the embodiment of the present invention has been disclosed for illustrative purposes, they are for specifically explaining the present invention. Therefore, a circuit board according to the preferred embodiments of the present invention is not limited thereto, but those skilled in the art will appreciate that various modifications and alteration are possible, without departing from the scope and spirit of the invention as disclosed in the accompanying claims.

Accordingly, such modifications and alterations should also be understood to fall within the scope of the present invention. A specific protective scope of the present invention could be defined by accompanying claims.

What is claimed is:

1. A circuit board comprising:
an insulating material;
a build-up layer formed on one surface of the insulating material, and including at least one circuit layer and at least one insulating layer; and
a metal layer formed on the other surface of the insulating material and electrically disconnected from the circuit layer.

2. The circuit board as set forth in claim 1, further comprising a first solder resist layer formed on the build-up layer.

3. The circuit board as set forth in claim 2, wherein the first solder resist layer includes an opening part exposing a portion of an outermost circuit layer included in the build-up layer.

4. The circuit board as set forth in claim 3, further comprising a surface treatement layer formed on the outermost circuit layer exposed through the opening part.

5. The circuit board as set forth in claim 1, further comprising a second solder resist layer formed on the metal layer.

6. The circuit board as set forth in claim 1, wherein the circuit layer is made of copper (Cu).

7. The circuit board as set forth in claim 1, wherein the metal layer is selected from the group consisting of copper (Cu), nickel (Ni), silver (Ag), or an alloy thereof.

8. The circuit board as set forth in claim 1, wherein the metal layer is formed of a plurality of layers.

9. The circuit board as set forth in claim 8, wherein each of the metal layers is made of different kinds of metals.
